(19) United States
(12) Patent Application Publication
(10) Pub. No.: US 2012/0326131 A1
(43) Pub. Date: Dec. 27, 2012

(54) ORGANIC LIGHT EMITTING DIODE DISPLAY

(75) Inventor: Byung-Uk Han, Yongin-city (KR)

(73) Assignee: Samsung Mobile Display Co., Ltd., Yongin-city (KR)

(21) Appl. No.: 13/251,994

(22) Filed: Oct. 3, 2011

(30) Foreign Application Priority Data
Jun. 27, 2011 (KR) 10-2011-0062461

(51) Int. Cl. H01L 27/32; H01L 27/30

(52) U.S. Cl. 257/40; 257/E27.118; 257/E27.119

(57) ABSTRACT

A solar cell integrated organic light emitting diode (OLED) display is disclosed. In one embodiment, the organic light emitting diode (OLED) display includes i) a substrate, ii) an organic light emitting element formed on the substrate and including a reflection electrode, an organic emission layer, and a transparent electrode sequentially deposited from the substrate. The OLED display may further include a solar cell unit positioned on the organic light emitting element and an encapsulation member positioned on one of the organic light emitting element and the solar cell unit.

### RELATED APPLICATIONS

This application claims priority to and the benefit of Korean Patent Application No. 10-2011-0062461 filed in the Korean Intellectual Property Office on Jun. 27, 2011, the entire contents of which are incorporated herein by reference.

### BACKGROUND

1. Field

The described technology generally relates to an organic light emitting diode (OLED) display, more particularly, to a solar cell integral type of OLED display.

2. Description of the Related Technology

An OLED display has self-luminance characteristics, and unlike a liquid crystal display (LCD), the thickness and weight thereof can be reduced since a separate light source is not required. Further, because the OLED display has high quality characteristics such as low power consumption, high luminance, and high reaction speed, the OLED display is appropriate for use in a mobile electronic device.

### SUMMARY

One inventive aspect is an organic light emitting diode (OLED) display that improves power consumption by dualizing an energy source by using a solar cell as an inner energy source as well as an outer energy source such as a rechargeable battery through an implement of the solar cell.

Another aspect is an organic light emitting diode (OLED) display that increases generation efficiency of a solar cell by optimizing a mounting position of a solar cell.

Another aspect is an organic light emitting diode (OLED) display, which includes: a substrate; an organic light emitting element formed on the substrate and including a reflection electrode, an organic emission layer, and a transparent electrode sequentially deposited from the substrate; a solar cell positioned on the unit organic light emitting element; and an encapsulation member positioned on one of the organic light emitting element and the solar cell unit.

The encapsulation member may be positioned on the solar cell unit, and may be formed of a transparent insulation substrate. The solar cell unit may be formed with a deposition structure of a first transparent electrode, a light activation layer, and a second transparent electrode, and the transparent electrode and the first transparent electrode may be formed of one transparent electrode such that the organic light emitting element and the solar cell unit share the electrode.

The reflection electrode may be a hole injection electrode, and the transparent electrode may be an electron injection electrode.

The reflection electrode may be formed with a triple layer including a first layer, a second layer, and a third layer. The first layer and the third layer may include at least one of indium tin oxide (ITO), indium zinc oxide (IZO), indium oxide (In₂O₃), and zinc oxide (ZnO), and the second layer may include at least one of silver (Ag) and aluminum (Al). The transparent electrode may be formed of a magnesium (Mg)-silver (Ag) alloy layer.

The first transparent electrode may be a cathode collecting electrons, and the second transparent electrode may be an anode collecting holes and is connected to the reflection electrode through an external circuit. The second transparent electrode may be formed of a dual layer of zinc sulfide (ZnS) and silver (Ag).

The reflection electrode may be an electron injection electrode, and the transparent electrode may be a hole injection electrode. The reflection electrode may include aluminum (Al), and the transparent electrode may be formed of a dual layer of zinc sulfide (ZnS) and silver (Ag).

The first transparent electrode may be an anode collecting holes, and the second transparent electrode may be a cathode collecting electrons and that is connected to the reflection electrode through an external circuit. The second transparent electrode may include at least one of indium tin oxide (ITO), indium zinc oxide (IZO), indium oxide (In₂O₃), and zinc oxide (ZnO).

The organic light emitting diode (OLED) display may further include a sealant enclosing the organic light emitting element and the solar cell unit, and is positioned between the substrate and the encapsulation member. The sealant may include at least one of glass frit and an epoxy-based polymer resin.

The encapsulation member may be formed with a thin film encapsulation positioned between the organic light emitting element and the solar cell unit, and may include a plurality of inorganic layers and a plurality of organic layers. The encapsulation member may have a thickness of 2 μm to 10 μm, and transmits light emitted from the organic light emitting element.

The solar cell unit may be formed with a deposition structure of the first transparent electrode, the light activation layer, and the second transparent electrode. One of the reflection electrode and the transparent electrode may be a hole injection electrode, and the other may be an electron injection electrode. One of the first transparent electrode and the second transparent electrode may be a cathode collecting electrons, and the other may be an anode collecting holes.

The cathode may be connected to the electron injection electrode through an external circuit, and the anode may be connected to the hole injection electrode through an external circuit.

The organic light emitting diode (OLED) display may further include a second encapsulation member covering the solar cell unit. The second encapsulation member may be formed with a transparent insulation substrate.

The organic light emitting diode (OLED) display may further include a sealant enclosing the organic light emitting element and the solar cell unit and positioned between the substrate and the second encapsulation member. The sealant may include an epoxy-based polymer resin.

The solar cell unit may be formed of an organic thin film solar cell. The light activation layer may include soluble polythiophene (P3HT) as a donor material and a C₆₀ derivative (fullerene derivatives) (PCBM) as an acceptor material.

### BRIEF DESCRIPTION OF THE DRAWINGS

FIG. 1 is a cross-sectional view of an organic light emitting diode (OLED) display according to a first embodiment.

FIG. 2 is an enlarged cross-sectional view of the organic light emitting element and the solar cell unit shown in FIG. 1.

FIG. 3 is a partially enlarged cross-sectional view of a portion of a driving circuit unit, the organic light emitting element, and the solar cell unit shown in FIG. 1.

FIG. 4 is an enlarged cross-sectional view of an organic light emitting element and a solar cell unit of an organic light emitting diode (OLED) display according to a second embodiment.

FIG. 5 is a schematic cross-sectional view of an organic light emitting diode (OLED) display according to a third embodiment.

FIG. 6 is a partially enlarged cross-sectional view of a portion of a driving circuit unit, the organic light emitting element, and the solar cell unit shown in FIG. 5.

FIG. 7 is a schematic cross-sectional view of an organic light emitting diode (OLED) display according to a fourth embodiment.

### DETAILED DESCRIPTION

A usage environment of a portable electronic device such as a smart phone has recently varied into word processing, web browsing, electronic games, and multimedia contents watching such that usage time and usage frequency of the display device have increased. Accordingly, although the power consumption of the OLED display is low compared with other display devices, improvement of the power consumption is advantageous.

Embodiments will be described more fully hereinafter with reference to the accompanying drawings. As those skilled in the art would realize, the described embodiments may be modified in various different ways.

In the drawings, the thickness of layers, films, regions, etc., may be exaggerated for clarity. It will be understood that when an element such as a layer, film, region, or substrate is referred to as being “on” another element, it can be directly on the other element or intervening elements may also be present. By contrast, it will be understood that when an element is referred to as being “directly on” another element, intervening elements are not present.

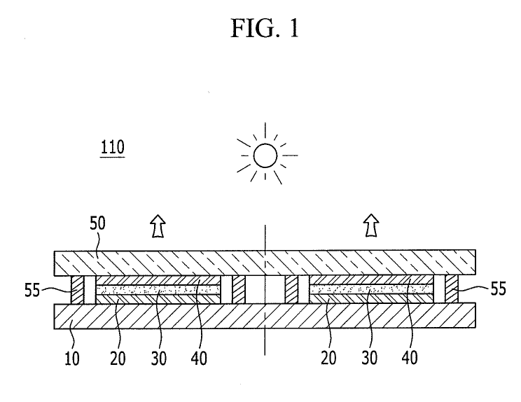

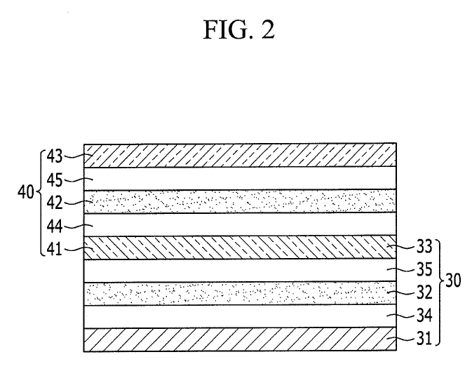

FIG. 1 is a cross-sectional view of an organic light emitting diode (OLED) display according to a first embodiment, and FIG. 2 is an enlarged cross-sectional view of the organic light emitting element and the solar cell unit shown in FIG. 1.

Referring to FIG. 1 and FIG. 2, an organic light emitting diode (OLED) display 110 includes a substrate 10, an organic light emitting element 30 formed on the substrate 10, a solar cell unit 40 formed on the organic light emitting element 30, and an encapsulation member 50 formed on the solar cell unit 40.

The substrate 10 is formed of an insulating substrate such as glass, quartz, ceramic, or plastic film. The substrate 10 is not a substrate to which light emitted from the organic light emitting element 30 is transmitted or outer light for operation of the solar cell unit 40 is transmitted. Thus, the substrate 10 may be an opaque insulation substrate.

The driving circuit unit 20 is formed on the substrate 10 and may include a plurality of thin film transistors and at least one capacitor. The driving circuit unit 20 is electrically connected to the organic light emitting element 30 to drive the organic light emitting element 30. The organic light emitting element 30 emits light according to a driving signal transmitted from the driving circuit unit 20. In FIG. 1, the driving circuit unit 20 and the organic light emitting element 30 are schematically shown as one layer.

The solar cell unit 40 may be formed directly on the organic light emitting element 30, and may be formed of an organic thin film type of solar cell. Referring to FIG. 2, the organic light emitting element 30 is basically made of a deposition structure of a reflection electrode 31, an organic emission layer 32, and a transparent electrode 33. The reflection electrode 31 is positioned closest to the substrate 10, and the transparent electrode 33 is positioned farthest away from the substrate 10. Also, the solar cell unit 40 is made of a deposition structure of a first transparent electrode 41, a light activation layer 42, and a second transparent electrode 43.

In the first embodiment, the transparent electrode 33 of the organic light emitting element 30 and the first transparent electrode 41 of the solar cell unit 40 are made of one transparent electrode layer. That is, the organic light emitting element 30 and the solar cell unit 40 are made of a structure in which the electrode is shared.

Accordingly, the structure of the organic light emitting element 30 and the solar cell unit 40 may be simplified and the organic light emitting element 30 and the solar cell unit 40 may be continuously manufactured, and thereby the manufacturing process may be simplified. Also, electrons or holes collected in the first transparent electrode 41 are directly supplied to the organic light emitting element 30, thereby increasing power usage efficiency. The detail structure and operation of the organic light emitting element 30 and the solar cell unit 40 will be described later.

The encapsulation member 50 is arranged opposite to the substrate 10 via the organic light emitting element 30 and the solar cell unit 40. Also, a sealant 55 enclosing the organic light emitting element 30 and the solar cell unit 40 is positioned between the substrate 10 and the encapsulation member 50. The substrate 10 and the encapsulation member 50 may be integrally combined by the sealant 55.

If the organic light emitting element 30, particularly the organic emission layer 32, is exposed to moisture or oxygen from the outside, a light emitting characteristic and a life-span characteristic are deteriorated. The encapsulation member 50 and the sealant 55 encloses the organic light emitting element 30 to prevent the moisture and oxygen from penetrating into the organic light emitting element 30.

In the first embodiment, the encapsulation member 50 is made of a transparent insulation substrate such as a transparent glass substrate or a transparent polymer film. In the case of the transparent polymer film, the encapsulation member 50 has flexibility. The encapsulation member 50 has a function of a display substrate transmitting light emitted from the organic light emitting element 30 as well as a function of an encapsulation member protecting the organic light emitting element 30 and the solar cell unit 40. That is, the encapsulation member 50 is positioned at the side facing a viewer where external light shines to the organic light emitting diode (OLED) display 110.

In one embodiment, the sealant 55 includes glass frit or an epoxy-based polymer resin. The sealant 55 including the glass frit has excellent vapor transmission resistance, and the sealant 55 of the epoxy-based polymer resin has excellent vapor transmission resistance and suppresses deterioration such as breakage in the manufacturing process.

The above-described organic light emitting diode (OLED) display 110 may be manufactured through processes of forming a plurality of driving circuit units 20, a plurality of organic light emitting elements 30, and a plurality of solar cell units 40 on one mother substrate, combining the substrate 10 and the encapsulation member 50 by using the sealant 55, and cutting at a portion between neighboring sealant 55 areas to divide each organic light emitting diode (OLED) display 110. In FIG. 1, the cutting line is indicated by a dash-dot line.

In the cutting process, the sealant 55 stably protects the organic light emitting element 30, and particularly in the case of the sealant 55 including the epoxy-based polymer resin, deterioration such as the breakage may be effectively suppressed.

Referring to FIG. 2, the organic light emitting element 30 is formed with the deposition structure of the reflection electrode 31, the organic emission layer 32, and the transparent electrode 33. Also, the solar cell unit 40 has a deposition structure of the first transparent electrode 41, the light activation layer 42, and the second transparent electrode 43. In one embodiment, the transparent electrode 33 of the organic light emitting element 30 and the first transparent electrode 41 of the solar cell unit 40 are formed of one transparent electrode such that the organic light emitting element 30 and the solar cell unit 40 share the transparent electrode.

The reflection electrode 31 of the organic light emitting element 30 may be a hole injection electrode (anode), and the transparent electrode 33 may be an electron injection electrode (cathode). In one embodiment, at least one of the hole injection layer (HIL) and the hole transport layer (HTL) is disposed between the organic emission layer 32 and the reflection electrode 31, and at least one of the electron injection layer (EIL) and the electron transport layer (ETL) is disposed between the organic emission layer 32 and the transparent electrode 33.

In FIG. 2, the reflection electrode 31, a hole transport layer (HTL) 34, the organic emission layer 32, an electron transport layer (ETL) 35, and the transparent electrode 33 are sequentially deposited to form the organic light emitting element 30.

In one embodiment, the reflection electrode 31 is formed of a conducting material having a high work function, and the transparent electrode 33 is formed of a conducting material having a low work function.

For example, the reflection electrode 31 may be formed of triple layers including indium tin oxide (ITO)/silver (Ag)/indium tin oxide (ITO). The reflection electrode 31 obtains the high work function by using indium tin oxide (ITO) and reflects by using silver (Ag). The indium tin oxide (ITO) may be replaced with indium zinc oxide (IZO), indium oxide (In₂O₃), and zinc oxide (ZnO), and the silver (Ag) may be replaced with aluminum (Al).

In one embodiment, the transparent electrode 33 is formed with a metal layer having a thickness of a degree that light may be transmitted therethrough. For example, the transparent electrode 33 may be formed of a magnesium (Mg)-silver (Ag) alloy layer.

If the holes and the electrons are respectively injected to the organic emission layer 32 from the reflection electrode 31 and the transparent electrode 33, excitons of which the electrons and holes are combined are generated in the organic emission layer 32, and the light emitting is realized by energy generated when the excitons drop from an exited state to a ground state. The organic light emitting diode (OLED) display 110 displays images by this light emission.

In the solar cell unit 40, the first transparent electrode 41 is the cathode collecting the electrons, and the second transparent electrode 43 is the anode collecting the holes. In one embodiment, the second transparent electrode 43 is formed of the conducting material having the higher work function than the first transparent electrode 41, and is formed of the metal layer having the thin thickness such that light may be transmitted therethrough. For example, the second transparent electrode 43 may be formed of dual layers including zinc sulfide (ZnS)/silver (Ag).

The light activation layer 42 may be formed of a dual structure (D/A bi-layer) including a donor (electron donor, D) material and an acceptor (electron acceptor, A) material or a complex structure ((D+A) blend). On the other hand, the light activation layer 42 may be formed of a structure in which the complex structure ((D+A) blend) is deposited between the donor layer and the acceptor layer.

Also, an n-buffer layer 44 may be positioned between the first transparent electrode 41 and the light activation layer 42, and a p-buffer layer 45 may be positioned between the light activation layer 42 and the second transparent electrode 43. The n-buffer layer 44 functions as the electron transport layer (ETL) and the p-buffer layer 45 functions as the hole transport layer (HTL) to increase photoelectric efficiency of the solar cell unit 40.

As the donor material of the light activation layer 42, a poly(para-phenylene vinylene) (PPV)-based material, polythiophene (PT) derivatives, a polyfluorene (PF)-based material, and copolymers thereof, or crystalline polymer soluble polythiophene (P3HT) may be used. In one embodiment, the donor material has a photoabsorption wavelength range within a sunlight spectrum, and high photoabsorption and charge mobility.

As the acceptor material of the light activation layer 42, C₆₀ itself or a C₆₀ derivative (fullerene derivative) (PCBM) designed for C₆₀ to be well dissolved in an organic solvent may be used. The acceptor material has a larger electron affinity and charge mobility than the donor material. When the light activation layer 42 includes the donor material of P3HT and the acceptor material of PCBM, the photoelectric efficiency is highest.

If the light is applied to the solar cell unit 40 through the encapsulation member 50, the light is absorbed in the donor material of the light activation layer 42 such that the excitons of the exited state are generated, and the excitons are diffused in an arbitrary direction and are then divided into electrons and holes in the interface with the acceptor material. The remaining holes in the donor layer are moved to the second transparent electrode 43 by an electric field formed by a difference of work functions between the first and second transparent electrodes 41 and 43 and the concentration difference of the stacked charges, and the electrons are moved to the first transparent electrode 41 according to the inner part of the acceptor layer to be collected.

The electrons collected into the first transparent electrode 41 are directly supplied to the organic emission layer 32 of the organic light emitting element 30 without passing through an external circuit. Also, the holes collected into the second transparent electrode 43 are supplied into the reflection electrode 31 of the organic light emitting element 30 through an external circuit.

As described above, the solar cell unit 40 directly supplies the electrons and the holes to the transparent electrode 33 and the reflection electrode 31 of the organic light emitting element 30, thereby functioning as an inner energy source. That is, the organic light emitting diode (OLED) display 110 includes an external energy source such as a rechargeable battery, and simultaneously the solar cell unit 40 as the inner energy source assists the external energy source. As a result, the organic light emitting diode (OLED) display 110 dualizes the energy source, thereby improving power consumption.

Also, the light emitted from the organic emission layer 32 is emitted outside through the solar cell unit 40 such that the photoelectric conversion action like at a time when the sunlight is provided from the light activation layer 42 of the solar cell unit 40 is generated when the light of the organic emission layer 32 is transmitted through the solar cell unit 40

Accordingly, the inner light energy from the organic light emitting element 30 as well as the sunlight may be re-used.

The solar cell unit 40 is formed with a minimum thickness within a range such that each layer of the solar cell unit 40 executes the function itself, thereby realizing the translucent characteristic. Accordingly, the solar cell unit 40 minimizes deterioration of the transmission of light emitted from the organic light emitting element 30 such that the realization of a front light emitting type is possible.

Also, the solar cell unit 40 including the organic thin film type solar cell uses the organic material having a relatively low cost and a solution process is possible such that mass production using an ink-jet or a roll-to-roll printing method is possible, thereby reducing manufacturing cost. Also, the solar cell unit 40 may be manufactured in a low temperature process such that thermal damage to the organic light emitting element 30 may be prevented.

The solar cell unit 40 may be formed directly on the organic light emitting element 30 or may be combined with the organic light emitting element 30 after being formed on the encapsulation member 50. That is, in the latter case, the driving circuit unit 20 and the organic light emitting element 30 are formed on the substrate 10 and the solar cell unit 40 is formed on the encapsulation member 50, and then the substrate 10 and the encapsulation member 50 are combined by using the sealant 55, thereby completing the organic light emitting diode (OLED) display 110 such that the solar cell unit 40 is secured to the organic light emitting element 30.

In the former case in which the organic light emitting element 30 and the solar cell unit 40 are separately formed on the substrate 10 and the encapsulation member 50, the manufacturing efficiency may be increased compared with the latter case such that the defect rate may be reduced and productivity may be increased.

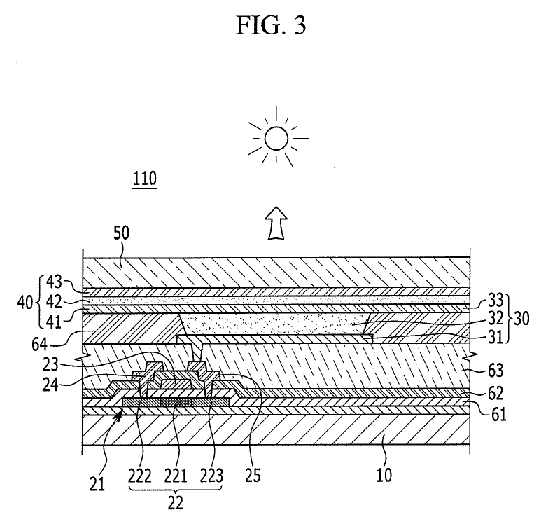

FIG. 3 is a partially enlarged cross-sectional view of a portion of a driving circuit unit, the organic light emitting element, and the solar cell unit shown in FIG. 1. The organic light emitting diode (OLED) display 110 includes a plurality of pixels, and FIG. 3 schematically shows one pixel. In FIG. 1 and FIG. 3, the arrow represents a light progressing direction of the light emitted from the organic light emitting element 30.

The driving circuit unit 20 includes at least two thin film transistors including a switching thin film transistor and a driving thin film transistor 21 and at least one capacitor. The switching thin film transistor has a function of selecting a pixel to be light-emitted, and the driving thin film transistor 21 has a function of applying a driving voltage to the reflection electrode 31 of the selected pixel. FIG. 3 shows the driving thin film transistor 21 and the organic light emitting element 30 connected thereto.

The driving thin film transistor 21 includes a semiconductor layer 22, a gate electrode 23, a source electrode 24, and a drain electrode 25. The semiconductor layer 22 includes a channel region 221 and a source region 222 and drain region 223 disposed on respective sides of the channel region 221. The gate electrode 23 is positioned on the channel region 221 via a gate insulating layer 61. The source electrode 24 and the drain electrode 25 are formed on an interlayer insulating layer 62 covering the gate electrode 23 and are respectively connected to the source region 222 and the drain region 223 through contact holes.

A planarization layer 63 is positioned on the source electrode 24 and the drain electrode 25, and the reflection electrode 31 of the organic light emitting element 30 is positioned on the planarization layer 63. The reflection electrode 31 as the pixel electrode is divided per pixel, and is connected to the drain electrode 25 of the driving thin film transistor 21. The organic emission layer 32 is formed on the reflection electrode 31, and the transparent electrode 33 covers the organic emission layer 32. The transparent electrode 33 as a common electrode is formed for a plurality of pixels.

The transparent electrode 33 is the first transparent electrode 41 of the solar cell unit 40, and the n-buffer layer 44, the light activation layer 42, the p-buffer layer 45, and the second transparent electrode 43 are sequentially deposited on the first transparent electrode 41 thereby forming the solar cell unit 40. Each layer of the solar cell unit 40 is commonly formed through a plurality of pixels. Accordingly, it is not necessary for the solar cell unit 40 to be separately patterned such that the manufacturing process of the solar cell unit 40 may be simplified.

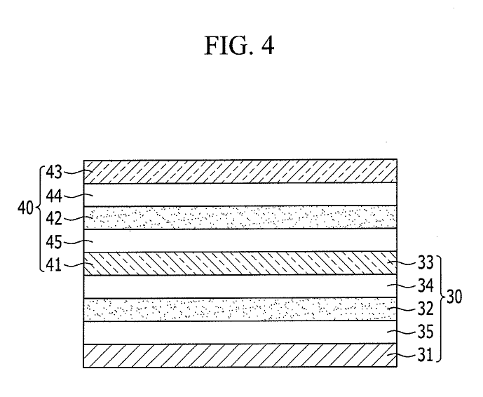

FIG. 4 is an enlarged cross-sectional view of an organic light emitting element and a solar cell unit of an organic light emitting diode (OLED) display according to a second embodiment.

Referring to FIG. 4, an organic light emitting diode (OLED) display is the same as the organic light emitting diode (OLED) display of the first embodiment except that the functions of i) the reflection electrode 31 and the transparent electrode 33 of the organic light emitting element 30, and ii) the first and second transparent electrodes 41 and 43 of the solar cell unit 40 are reversed with regard to the first embodiment. The same members as in the first embodiment are indicated by like reference numerals, and differences from the first embodiment will be mainly described.

In the second embodiment, the reflection electrode 31 of the organic light emitting element 30 is the electron injection electrode (cathode), and the transparent electrode 33 is the hole injection electrode (anode). In this embodiment, at least one of the electron injection layer (EIL) and the electron transport layer (ETL) is disposed between the organic emission layer 32 and the reflection electrode 31, and at least one of the hole injection layer (HIL) and the hole transport layer (HTL) is disposed between the organic emission layer 32 and the transparent electrode 33.

In FIG. 4, the reflection electrode 31, the electron transport layer (ETL) 35, the organic emission layer 32, the hole transport layer (HTL) 34, and the transparent electrode 33 are sequentially deposited to form the organic light emitting element 30.

In one embodiment, the reflection electrode 31 of the organic light emitting element 30 is formed of the conducting material having the low work function, and the transparent electrode 33 is formed of the conducting material having the high work function. For example, the reflection electrode 31 may include aluminum (Al). Also, the transparent electrode 33 may be formed with a metal layer having a thin thickness such that light may be transmitted therethrough. For example, the transparent electrode 33 may be formed of a dual layer of zinc sulfide (ZnS)/silver (Ag).

In one embodiment, the first transparent electrode 41 of the solar cell unit 40 is the anode collecting the holes, and the second transparent electrode 43 is the cathode collecting the electrons. The second transparent electrode 43 may include at least one of indium tin oxide (ITO), indium zinc oxide (IZO), indium oxide (In₂O₃), and zinc oxide (ZnO).

The p-buffer layer 45 may be positioned between the first transparent electrode 41 and the light activation layer 42, and the n-buffer layer 44 may be positioned between the light activation layer 42 and the second transparent electrode 43. The p-buffer layer 45 functions as the hole transport layer (HTL) and the n-buffer layer 44 functions as the electron transport layer (ETL), thereby improving the photoelectric efficiency of the solar cell unit 40. The n-buffer layer 44 may be omitted if necessary.

If light is applied to the solar cell unit 40, the light is absorbed in the donor material of the light activation layer 42 such that the excitons of the exited state are generated, and the excitons are diffused in an arbitrary direction and are then divided into the electrons and holes in the interface with the acceptor material. The remaining holes in the donor layer are moved to the first transparent electrode 41 by the electric field formed by the difference of the work functions between the first and second transparent electrodes 41 and 43 and the concentration difference of the stacked charges, and the electrons are moved into the second transparent electrode 43 according to the inner part of the acceptor layer to be collected.

The holes collected in the first transparent electrode 41 are directly supplied to the organic emission layer 32 of the organic light emitting element 30 without passing through an external circuit. Also, the electrons collected into the second transparent electrode 43 are supplied to the reflection electrode 31 of the organic light emitting element 30 through an external circuit. As described above, the solar cell unit 40 is used as the inner energy source assisting the external energy source, thereby decreasing power consumption.

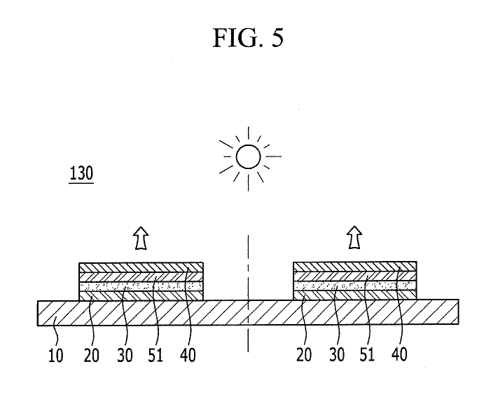

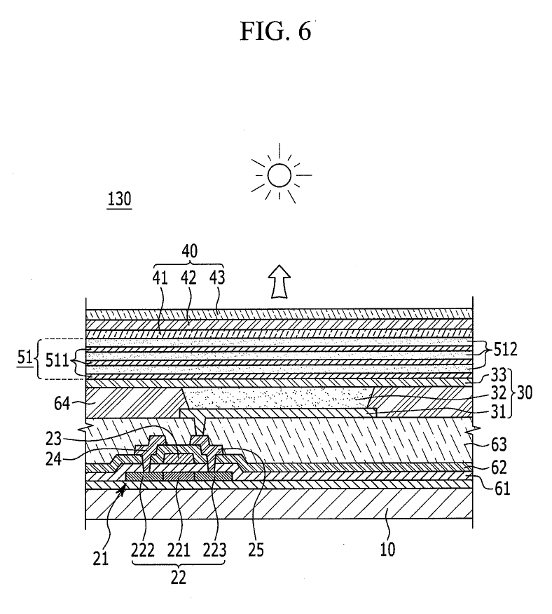

FIG. 5 is a schematic cross-sectional view of an organic light emitting diode (OLED) display according to the third embodiment, and FIG. 6 is a partially enlarged cross-sectional view of a portion of a driving circuit unit, the organic light emitting element, and the solar cell unit shown in FIG. 5. In FIG. 5 and FIG. 6, the arrow represents a light progressing direction of the light emitted from the organic light emitting element 30.

Referring to FIG. 5 and FIG. 6, the organic light emitting diode (OLED) display is similar to those of the first and second embodiments except that an encapsulation member 51 is disposed between the organic light emitting element 30 and the solar cell unit 40, and the sealant that is omitted. The same members as in the first and second embodiments are indicated by the same reference numerals, and differences from the first embodiment or the second embodiment will be described below.

In one embodiment, the encapsulation member 51 is formed of a thin film encapsulation layer, and is disposed between the organic light emitting element 30 and the solar cell unit 40. The organic light emitting element 30 and the solar cell unit 40 are separated via the encapsulation member 51 interposed therebetween such that the electrode is not shared, differently from the first and second embodiments.

The encapsulation member 51 includes a plurality of inorganic layers 511 and a plurality of organic layers 512, and is a multilayer structure in which the inorganic layers 511 and the organic layers 512 are alternately deposited one by one. The inorganic layer 511 suppresses moisture and oxygen extremely well, and the organic layer 512 has a good flatness characteristic for smoothing stress between layers and has a function of filling minute cracks and pin holes of the inorganic layer 511. The inorganic layer 511 may be formed of silicon nitride or silicon oxide, and the organic layer 512 may be formed of an acryl-based resin.

The entire thickness of the encapsulation member 51 may be in the range of about 2 μm to about 10 μm. The encapsulation member 51 transmits the light emitted from the organic light emitting element 30. If the thickness of the encapsulation member 51 is less than about 2 μm, the moisture transmission resistance may be deteriorated, and if it is more than about 10 μm, the transmittance may be decreased. However, depending on the embodiment, the thickness of the encapsulation member 51 may be greater than about 10 μm or less than about 2 μm.

The organic light emitting element 30 includes the reflection electrode 31, the organic emission layer 32, and the transparent electrode 33. When the reflection electrode 31 is the hole injection electrode (anode), the transparent electrode 33 is the electron injection electrode (cathode), and when the reflection electrode 31 is the electron injection electrode (cathode), the transparent electrode 33 is the hole injection electrode (anode). In two cases, the reflection electrode 31 is the pixel electrode divided per pixel, and the transparent electrode 33 is the common electrode formed through a plurality of pixels.

The encapsulation member 51 and the solar cell unit 40 are commonly formed through a plurality of pixels. Particularly, the solar cell unit 40 including the organic thin film type solar cell is formed on the encapsulation member 51 such that the solar cell unit 40 has a function of smoothing mechanical stress of the encapsulation member 51.

The solar cell unit 40 includes the first transparent electrode 41, the light activation layer 42, and the second transparent electrode 43. When the first transparent electrode 41 is the cathode collecting the electrons, the second transparent electrode 43 is the anode collecting the holes, and when the first transparent electrode 41 is the anode collecting the holes, the second transparent electrode 43 is the cathode collecting the electrons.

The cathode of the solar cell unit 40 is connected to the electron injection electrode of the organic light emitting element 30 through the external circuit, and the anode is connected to the hole injection electrode of the organic light emitting element 30 through the external circuit. In the solar cell unit 40, the p-buffer layer 45 functioning as the hole transport layer (HTL) may be disposed between the anode and the light activation layer 42, and the n-buffer layer 44 functioning as the electron transport layer (ETL) may be disposed between the cathode and the light activation layer 42.

The above-described organic light emitting diode (OLED) display 130 may be manufactured through processes of forming a plurality of driving circuit units 20, a plurality of organic light emitting elements 30, a plurality of encapsulation members 51, and a plurality of solar cell units 40 on one mother substrate, and cutting the mother substrate to divide it into each organic light emitting diode (OLED) display 130. In FIG. 5, the cutting line is indicated by the dash-dot line.

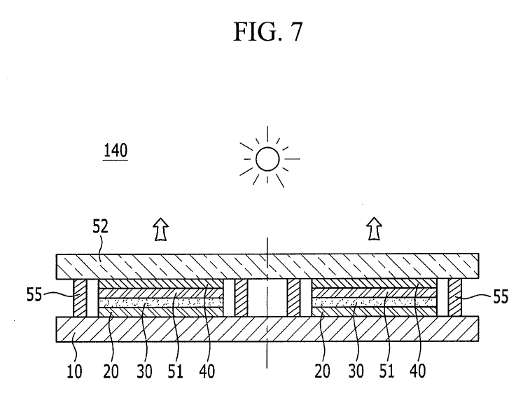

FIG. 7 is a cross-sectional view of an organic light emitting diode (OLED) display according to a fourth embodiment.

Referring to FIG. 7, the organic light emitting diode (OLED) display 140 has the same structure as the organic light emitting diode (OLED) display of the third embodiment except for the encapsulation member of the dual structure of the first encapsulation member 51 and a second encapsulation member 52. The same members as in the third embodiment are indicated by like reference numerals, and differences from the third embodiment will be mainly described.

In the fourth embodiment, the first encapsulation member 51 is positioned between the organic light emitting element 30 and the solar cell unit 40, and the second encapsulation member 52 covers the solar cell unit 40. In one embodiment, the first encapsulation member 51 is formed of the thin film encapsulation layer, and the second encapsulation member 52 is formed of the transparent insulation substrate. The second encapsulation member 52 may be formed on a transparent glass substrate or a transparent polymer film.

Also, the sealant 55 enclosing the organic light emitting element 30, the first encapsulation member 51, and the solar cell unit 40 is positioned between the substrate 10 and the second encapsulation member 52. The substrate 10 and the second encapsulation member 52 are integrally combined by the sealant 55.

The second encapsulation member 52 and the sealant 55 assist the moisture transmission resistance of the first encapsulation member 51, and simultaneously increase the mechanical integrity of the organic light emitting diode (OLED) display 140, thereby improving durability. The first encapsulation member 51 is relatively weak with regard to moisture penetrating in the side direction such that the moisture transmission resistance may be compensated by the sealant 55 enclosing the first encapsulation member 51.

In the fourth embodiment, the sealant 55 may includes the epoxy based polymer resin instead of the glass flit. The first encapsulation member 51 is positioned inside the sealant 55 such that the penetration of the moisture and the oxygen is suppressed to some degree, and although the sealant 55 is formed of the epoxy based polymer resin that has poorer moisture transmission resistance than the glass frit, it has a lower cost as a sealant material, and there is no impact on the encapsulation function of the organic light emitting element 30.

Also, the sealant of the epoxy material is not easily damaged by an external impact such that the deterioration generation in the cutting process of the substrate 10 and the second encapsulation member 52 may be prevented.

The above organic light emitting diode (OLED) display 140 may be manufactured through the processes of forming a plurality of driving circuit units 20, a plurality of organic light emitting elements 30, a plurality of first encapsulation members 51, and a plurality of solar cell units 40 on one mother substrate, combining the substrate 10 and the second encapsulation member 52 by using a sealant 55, and cutting at a portion between the neighboring sealants 55 to divide it into each organic light emitting diode (OLED) display 140. In FIG. 7, the cutting line is indicated by the dash-dot line.

According to at least one of the disclosed embodiments, the organic light emitting diode (OLED) display includes an external energy source such as a rechargeable battery, and the solar cell unit may simultaneously use the inner energy source to assist the external energy source. Accordingly, the energy source may be dualized such that power consumption may not only be improved but also the inner photo-energy of the organic light emitting element may be used again, and thereby the power consumption may be further effectively reduced.

While the disclosed embodiments have been described in connection with the accompanying drawings, it is to be understood that the disclosed embodiments are not considered limiting, but, on the contrary, they are intended to cover various modifications and equivalent arrangements included within the spirit and scope of the appended claims.

What is claimed is:

1. An organic light emitting diode (OLED) display comprising:
a substrate;
an organic light emitting element formed on the substrate and including a reflection electrode, an organic emission layer, and a transparent electrode sequentially formed on the substrate;
a solar cell unit positioned on the organic light emitting element; and
an encapsulation member positioned on one of the organic light emitting element and the solar cell unit.

2. The organic light emitting diode (OLED) display of claim 1, wherein the encapsulation member is positioned on the solar cell unit and is formed of a transparent insulation substrate.

3. The organic light emitting diode (OLED) display of claim 2, wherein the solar cell unit comprises a first transparent electrode, a light activation layer formed over the first transparent electrode, and a second transparent electrode formed over the light activation layer and
wherein the transparent electrode of the organic light emitting element and the first transparent electrode of the solar cell unit are formed of a single transparent electrode such that the organic light emitting element and the solar cell unit share the electrode.

4. The organic light emitting diode (OLED) display of claim 3, wherein the reflection electrode is a hole injection electrode, and wherein the transparent electrode is an electron injection electrode.

5. The organic light emitting diode (OLED) display of claim 4, wherein the reflection electrode is formed with a triple layer including a first layer, a second layer, and a third layer,
wherein the first layer and the third layer contain at least one of indium tin oxide (ITO), indium zinc oxide (IZO), indium oxide (In₂O₃), and zinc oxide (ZnO), and
wherein the second layer contains at least one of silver (Ag) and aluminum (Al).

6. The organic light emitting diode (OLED) display of claim 4, wherein the transparent electrode of the organic light emitting element is formed at least partially of a magnesium (Mg)-silver (Ag) alloy layer.

7. The organic light emitting diode (OLED) display of claim 4, wherein the first transparent electrode is a cathode configured to collect electrons; and
wherein the second transparent electrode is an anode configured to collect holes and is electrically connected to the reflection electrode through an external circuit.

8. The organic light emitting diode (OLED) display of claim 7, wherein the second transparent electrode is formed at least partially of a dual layer of zinc sulfide (ZnS) and silver (Ag).

9. The organic light emitting diode (OLED) display of claim 3, wherein the reflection electrode is an electron injection electrode and the transparent electrode is a hole injection electrode.

10. The organic light emitting diode (OLED) display of claim 9, wherein the reflection electrode is formed at least partially of aluminum (Al), and
wherein the transparent electrode is formed at least partially of a dual layer of zinc sulfide (ZnS) and silver (Ag).

11. The organic light emitting diode (OLED) display of claim 9, wherein the first transparent electrode is an anode configured to collect holes, and
wherein the second transparent electrode is a cathode configured to collect electrons and is electrically connected to the reflection electrode through an external circuit.

12. The organic light emitting diode (OLED) display of claim 11, wherein the second transparent electrode contains at least one of indium tin oxide (ITO), indium zinc oxide (IZO), indium oxide (In₂O₃), and zinc oxide (ZnO).

13. The organic light emitting diode (OLED) display of claim 2, further comprising a sealant enclosing the organic light emitting element and the solar cell unit and positioned between the substrate and the encapsulation member,
wherein the sealant includes at least one of a glass frit and an epoxy-based polymer resin.

14. The organic light emitting diode (OLED) display of claim 1, wherein the encapsulation member is formed with a thin film encapsulation layer positioned between the organic light emitting element and the solar cell unit, and wherein the thin film encapsulation layer includes a plurality of inorganic layers and a plurality of organic layers.

15. The organic light emitting diode (OLED) display of claim 14, wherein the encapsulation member has a thickness of about 2 μm to about 10 μm, and is configured to transmit light emitted from the organic light emitting element.

16. The organic light emitting diode (OLED) display of claim 14, wherein the solar cell unit comprises the first transparent electrode, the light activation layer formed over the first transparent electrode, and the second transparent electrode formed over the light activation layer,
wherein one of the reflection electrode and the transparent electrode of the organic light emitting element is a hole injection electrode, and the other is an electron injection electrode; and
wherein one of the first and second transparent electrodes is a cathode configured to collect electrons and the other is an anode configured to collect holes.

17. The organic light emitting diode (OLED) display of claim 16, wherein the cathode is electrically connected to the electron injection electrode through the external circuit, and
wherein the anode is electrically connected to the hole injection electrode through the external circuit.

18. The organic light emitting diode (OLED) display of claim 14, further comprising a second encapsulation member covering the solar cell unit, wherein the second encapsulation member is formed with a transparent insulation substrate.

19. The organic light emitting diode (OLED) display of claim 18, further comprising a sealant enclosing the organic light emitting element and the solar cell unit and positioned between the substrate and the second encapsulation member, wherein the sealant is at least partially formed of an epoxy based polymer resin.

20. The organic light emitting diode (OLED) display of claim 1, wherein the solar cell unit is formed of an organic thin film solar cell, and
wherein the light activation layer contains soluble polythiophene (P3HT) as a donor material and a C₆₀ derivative (a fullerene derivatives) (PCBM) as an acceptor material.
